(19) United States
(12) Patent Application Publication
(10) Pub. No.: US 2017/0242625 A1
(43) Pub. Date: Aug. 24, 2017

(54) APPARATUS FOR SSD PERFORMANCE AND ENDURANCE IMPROVEMENT

(71) Applicant: SAMSUNG ELECTRONICS CO., LTD., Suwon-Si (KR)

(72) Inventors: Rajinikanth Pandurangan, Fremont, CA (US); Changho Choi, San Jose, CA (US)

(21) Appl. No.: 15/137,978

(22) Filed: Apr. 25, 2016

Related U.S. Application Data
(60) Provisional application No. 62/299,451, filed on Feb. 24, 2016.

(51) Int. Cl. G06F 3/06; G11C 16/10

(52) U.S. Cl. CPC G06F 3/0659; G11C 16/10; G06F 3/0604; G06F 3/0679

(57) ABSTRACT

A solid state drive including non-flash memory for storage of short-lifetime data and/or frequently updated data. The solid state drive is configured, when it receives a write command, to identify short lifetime data, and store it in non-flash memory, e.g., DRAM, instead of flash memory and store longer lifetime data to flash memory. When the non-flash memory is volatile memory (e.g., DRAM) the solid state drive may also include an energy storage device, such as a supercapacitor, to provide temporary power to move data from the volatile memory to flash memory if supply power is interrupted.

### CROSS-REFERENCE TO RELATED APPLICATION(S)

The present application claims priority to and the benefit of U.S. Provisional Application No. 62/299,451, filed Feb. 24, 2016, entitled “SSD PERFORMANCE AND ENDURANCE”, the entire content of which is incorporated herein by reference.

### FIELD

One or more aspects of embodiments according to the present invention relate to solid state drives, and more particularly to a system and method for improving the performance and endurance of a solid state drive.

### BACKGROUND

Solid state drives may use flash memory arranged in physical blocks, each containing a number of physical pages. A physical block may be the smallest unit of memory that is erasable in one operation, and a physical page may be the smallest unit of memory that can be written in one operation. Here, when a host connected to the solid state drive sends a command to erase or update, e.g., a physical page, the solid state drive may mark the physical page as invalid instead of erasing or overwriting the entire block containing the page (while sending any update to a different physical page). The invalid physical page may not be available for the storage of new data, however, until the physical block is erased. In addition, flash memory may have limited endurance, e.g., it may become unreliable after a certain number of rewrites.

Data items written to a solid state drive may have varying lifetimes, i.e., varying intervals of time during which they are stored before being erased or overwritten. Data items with short lifetimes may result in more frequent physical block erasures, and cause inefficiency in the solid state drive, and a reduction in endurance.

Thus, there is a need for a system and method of handling, in a solid state drive, data items with short lifetimes.

### SUMMARY

Aspects of embodiments of the present disclosure are directed toward a system and method of accommodating data items with short lifetimes in a solid state drive.

According to an embodiment of the present invention there is provided a solid state drive, including: a flash memory; a non-flash memory; a storage controller; and a storage interface, the storage controller being connected to the storage interface and configured to receive, through the storage interface, a plurality of write commands, each write command including: a data item to be written; and an attribute code, the storage controller being configured to store the data item in the flash memory, or only in the non-flash memory, based on the attribute code.

According to an embodiment of the present invention there is provided a solid state drive, including: a flash memory; a non-flash memory; a storage controller; and a storage interface, the storage controller being connected to the storage interface and configured to receive, through the storage interface, a plurality of write commands, each write command including: a data item to be written; and an attribute code, the storage controller being configured to store the data item in the flash memory or in the non-flash memory, based on the attribute code.

In one embodiment, the attribute code is a stream identifier classifying the write command into one of a plurality of categories based on estimated data item lifetime.

In one embodiment, the storing of the data item in the flash memory or in the non-flash memory, based on the attribute code includes: inferring an estimated lifetime of the data item from the attribute code; storing the data item in the flash memory when the estimated lifetime is greater than a lifetime threshold; and storing the data item in the non-flash memory when the estimated lifetime is not greater than a lifetime threshold.

In one embodiment, the attribute code is equal to one selected from the group consisting of: a first value when the data item has a lifetime that falls into a first range of lifetimes, a second value when the data item has a lifetime that falls into a second range of lifetimes, and a third value when the data item has a lifetime that falls into a third range of lifetimes, the first range, the second range, and the third range being non-overlapping, a lifetime in the first range being shorter than a lifetime in the second range and shorter than a lifetime in the third range, and the storing of the data item in the flash memory or in the non-flash memory, based on the attribute code includes: storing the data item in the non-flash memory when the attribute code takes the first value; and storing the data item in the flash memory when the attribute code takes the second value or the third value.

In one embodiment, the solid state drive includes an energy storage device capable of storing an amount of energy sufficient to power the solid state drive during a time interval longer than a time interval sufficient to copy all data from the non-flash memory into the flash memory.

In one embodiment, the energy storage device is a supercapacitor.

According to an embodiment of the present invention there is provided a system including: a host; and a solid state drive including: a flash memory; a non-flash memory; a storage controller; and a storage interface, the host being configured to send to the storage controller, through the storage interface, a plurality of write commands, each write command including: a data item to be written; and an attribute code, the storage controller being configured to store the data item in the flash memory or in the non-flash memory, based on the attribute code.

In one embodiment, the system is configured to define a plurality of stream identifiers, each associated with a respective host activity; the attribute code of each write command is a stream identifier of the plurality of stream identifiers; and the system is further configured: to select a first subset of the stream identifiers; to store the data item in the flash memory when the stream identifier is in the first subset; and to store the data item in the non-flash memory when the stream identifier is not in the first subset.

In one embodiment, the selecting, of the first subset of the plurality of stream identifiers includes: monitoring data lifetimes of data items in write commands associated with each of the stream identifiers; associating an average lifetime with each stream identifier; and selecting, as the subset, a set of stream identifiers associated with a lifetime greater than a first threshold.

In one embodiment, the storing of the data item in the flash memory or in the non-flash memory, based on the attribute code includes: inferring an estimated lifetime of the data item from the attribute code; storing the data item in the flash memory when the estimated lifetime is greater than a lifetime threshold; and storing the data item in the non-flash memory when the estimated lifetime is not greater than a lifetime threshold.

In one embodiment, the attribute code takes one of a first value, a second value, or a third value when the data item has a lifetime that falls into a first range of lifetimes, a second range of lifetimes, and a third range of lifetimes, respectively, the first range, the second range, and the third range being non-overlapping, a lifetime in the first range being shorter than a lifetime in the second range and shorter than a lifetime in the third range, and the storing of the data item in the flash memory or in the non-flash memory, based on the attribute code includes: storing the data item in the non-flash memory when the attribute code takes the first value; and storing the data item in the flash memory when the attribute code takes the second value or the third value.

In one embodiment, the storage interface conforms to a standard selected from the group consisting of: Serial Advanced Technology Attachment (SATA), Fibre Channel, Serial Attached SCSI (SAS), Non Volatile Memory Express (NVMe), Ethernet, and Universal Serial Bus (USB).

In one embodiment, the system includes a plurality of physical pages, and a size of the non-flash memory is an integer multiple of a size of a physical page.

In one embodiment, the system includes a plurality of physical pages, and a size of the non-flash memory is an integer multiple of a size of a physical block.

In one embodiment, the system includes an energy storage device capable of storing an amount of energy sufficient to power the solid state drive during a time interval longer than a time interval sufficient to copy all data from the non-flash memory into the flash memory.

In one embodiment, the energy storage device is a supercapacitor.

According to an embodiment of the present invention there is provided a method for storing data, the method including: sending, by a host, through a storage interface, to a solid state drive including a flash memory and a non-flash memory, a plurality of write commands, each of the write commands including a data item to be stored and an attribute code, and storing the data item, based on the attribute code, either in the flash memory, or in the non-flash memory.

In one embodiment, the attribute code is a stream identifier classifying the write command into one of a plurality of categories based on estimated data item lifetime.

In one embodiment, the storing of the data item in the flash memory or in the non-flash memory, based on the attribute code includes: inferring an estimated lifetime of the data item from the attribute code; storing the data item in the flash memory when the estimated lifetime is greater than a lifetime threshold; and storing the data item in the non-flash memory when the estimated lifetime is not greater than a lifetime threshold.

In one embodiment, the attribute code is equal to one selected from the group consisting of: a first value when the data item has a lifetime that falls into a first range of lifetimes, a second value when the data item has a lifetime that falls into a second range of lifetimes, and a third value when the data item has a lifetime that falls into a third range of lifetimes, the first range, the second range, and the third range being non-overlapping, a lifetime in the first range being shorter than a lifetime in the second range and shorter than a lifetime in the third range, and the storing of the data item in the flash memory or in the non-flash memory, based on the attribute code includes: storing the data item in the non-flash memory when the attribute code takes the first value; and storing the data item in the flash memory when the attribute code takes the second value or the third value.

### BRIEF DESCRIPTION OF THE DRAWINGS

These and other features and advantages of the present invention will be appreciated and understood with reference to the specification, claims, and appended drawings wherein:

FIG. 1A is a block diagram of a host connected to a solid state drive, according to an embodiment of the present invention;

FIG. 1B is a block diagram of a plurality of physical pages in a physical block, according to an embodiment of the present invention;

FIG. 2 is a flowchart of a method for storing a data item, according to an embodiment of the present invention;

FIG. 3 is a diagram of a 16-bit unsigned integer, according to an embodiment of the present invention; and

FIG. 4 is a block diagram of a host connected to a solid state drive, according to an embodiment of the present invention.

### DETAILED DESCRIPTION

The detailed description set forth below in connection with the appended drawings is intended as a description of exemplary embodiments of an improvement of solid state drive (SSD) performance and endurance provided in accordance with the present invention and is not intended to represent the only foul's in which the present invention may be constructed or utilized. The description sets forth the features of the present invention in connection with the illustrated embodiments. It is to be understood, however, that the same or equivalent functions and structures may be accomplished by different embodiments that are also intended to be encompassed within the spirit and scope of the invention. As denoted elsewhere herein, like element numbers are intended to indicate like elements or features.

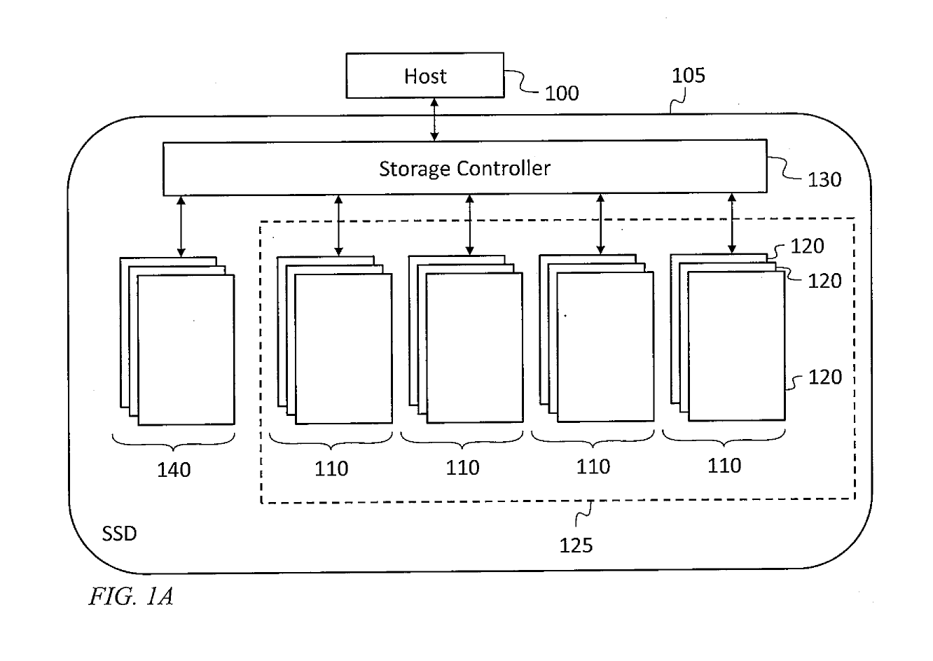

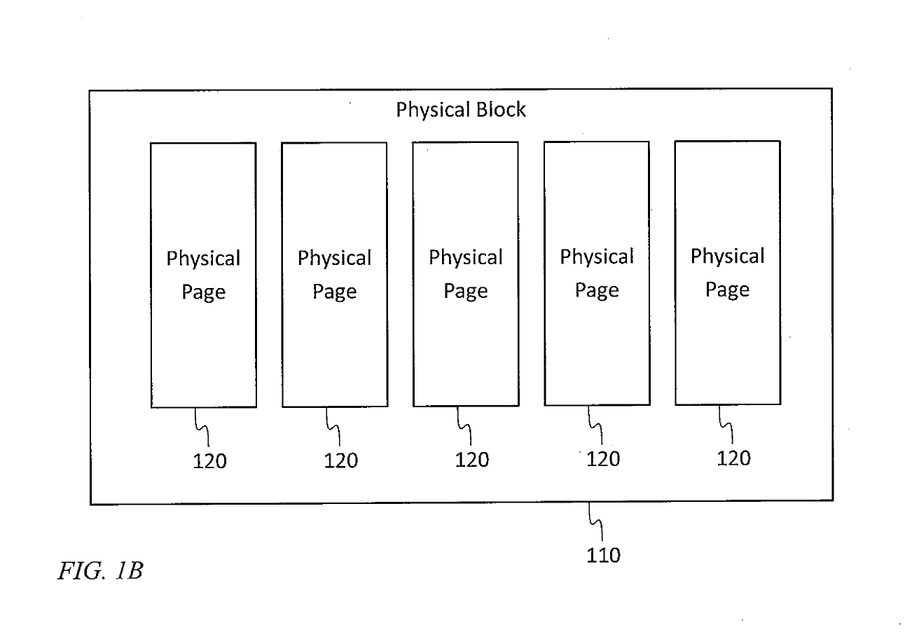

Referring to FIG. 1A, in one embodiment a host 100 is connected to a solid state drive (SSD) 105, and uses the solid state drive 105 for persistent storage. The solid state drive 105 may be a self-contained unit in an enclosure configured to provide persistent storage. It may be connected to the host 100 through a storage interface, e.g., through a connector and a protocol customarily used by a host 100 for storage operations. The connector and protocol may conform to, for example, Serial Advanced Technology Attachment (SATA), Fibre Channel, Serial Attached SCSI (SAS), Non Volatile Memory Express (NVMe), or to a more general-purpose interface such as Ethernet or Universal Serial Bus (USB). A flash memory 125 in the solid state drive 105 may be organized into physical blocks 110 (or “flash blocks” or “erase blocks”) and physical pages 120 (FIG. 1B is a block diagram of a plurality of physical pages 120 in a physical block 110). A physical block 110 may be the smallest unit of memory that is erasable in one operation, and a physical page 120 may be the smallest unit of memory that can be written in one operation. Each physical block 110 may include a plurality of physical pages 120. The host may interact with the mass storage device with storage access requests directed to logical page numbers, e.g., requesting data stored in a page at a logical page number, requesting that data be written to a page at a logical page number, or requesting that data stored in a page at a logical page number be erased. As used herein, a “physical page number” is an identifier (e.g., a number) that uniquely identifies a page within the mass storage device. For SSDs, static logical to physical (L-P) mappings are not used since the difference in read/write and erase sizes dictates a garbage control mechanism that is constantly moving data from one physical location to another, hence the need for a dynamic L-P map.

A flash translation layer may translate or map logical page numbers dynamically into physical page numbers. When new data is to be overwritten over data in a page at a logical page number, the flash translation layer may then mark the physical page 120 currently corresponding to the logical page number as invalid (instead of erasing the physical block 110 containing this physical page 120), update the mapping from logical page numbers to physical pages 120 to map the logical page number to a new physical page 120, and write the new data into the new physical page 120. Occasionally the flash translation layer may perform an operation referred to as “garbage collection”. In this operation, any physical block 110 that contains a large proportion (e.g., a proportion exceeding a set threshold) of physical pages 120 that have been marked as invalid may be erased, after the valid physical pages 120 remaining in the physical block 110 have been moved to physical pages 120 in one or more other physical blocks 110, causing the newly erased physical block 110 to be available for writing of new data. The flash translation layer may be implemented in software running on a storage controller 130 (e.g., a microcontroller) in the solid state drive 105.

The need to write remaining valid physical pages 120 in a first physical block 110 to other physical blocks 110 before erasing the first physical block may be referred to as write amplification. A write amplification factor may be defined as the average number of times a piece of data is written to the flash, as a result of the initial write and any additional writes resulting from garbage collection. If, for example, on average each piece of data is moved once (i.e., written a second time) as a result of garbage collection, the write amplification factor is 2. Write amplification may degrade both the performance and the endurance of the solid state drive 105, because additional writes cause delays and because flash memory may have a finite lifetime, as measured by the number of rewrites. The mean (average) lifetime of flash memory may be, for example, 10,000 rewrites, depending on the NAND type (e.g., whether it is SLC, MLC, TLC, or some other type).

It may be possible to reduce write amplification using multi-streaming. In this approach, data items being written to the drive are grouped or classified into streams according to the lifetime, or estimated or anticipated lifetime, of the data items. As used herein, a “data item” is a quantity of data that is written to the drive in one operation, e.g., as a result of the host 100 sending to the solid state drive 105 a write command containing the data item, and that subsequently expires (e.g., is erased or overwritten) at one point in time. A write command may contain one or more data items. Short-lived data items, e.g., data items that are likely to be erased or overwritten a short time after being written initially, may be referred to as “hot” data items, and may be associated with one or more streams of hot data items. Data items that are long-lived, e.g., expected to remain in the solid state drive 105 for a long period of time without being erased or overwritten may be referred to as “cold” data items and may be associated with one or more streams of cold data items. Similarly, data items of intermediate lifetime may be referred to as “warm” data items. As used herein, the “lifetime” of a data item is the time interval between the initial writing of the data item to the solid state drive 105, and the subsequent overwriting or erasure of the data item.

It may be the case that data items associated with, or generated by, certain activities of the host, e.g., having similar origins, or similar functions, have similar lifetimes. For example, data items generated by the same virtual machine, or by the same application, or by the same kind of operation in an application or a virtual machine, may have similar lifetimes. Accordingly the host may classify the data items into streams according to origin or function, and associate with each write command a stream identifier (ID), and the solid state drive 105 may use each physical block 110 only for data items with a shared stream identifier. In this embodiment, write amplification may be reduced because, for example, all of the data items in a physical block 110 containing hot data items may expire concurrently or substantially simultaneously (or waiting a relatively short time after some of them have expired may be sufficient to cause most of them to expire), so that to erase the physical block 110, it may be sufficient to move only a small number of remaining valid physical pages 120 to another physical block 110.

In some embodiments, the solid state drive 105 contains a quantity of non-flash memory such as DRAM 140 (e.g., a quantity of dynamic random access memory (DRAM)) that does not have the characteristics making write amplification important in flash memory. For example the non-flash memory may be capable of being erased in smaller increments than full blocks, and the non-flash memory may have significantly greater lifetime, as measured in rewrites, e.g., its expected lifetime may be 10¹⁵ rewrites. In some embodiments the non-flash memory is DRAM 140, but other kinds of memory (e.g., static random access memory (SRAM), or phase-change random access memory (PRAM)) may be used instead of DRAM 140. The DRAM 140 may be aligned with the page size of the flash memory 125, i.e., the amount of memory in the DRAM 140 may be an integer multiple of the size of a physical page 120 in the flash memory 125. The amount of memory in the DRAM 140 may also be an integer multiple of the size of a physical block 110 in the flash memory 125. The storage controller 130, under the control of firmware in the solid state drive 105, may manage the DRAM 140, e.g., it may perform read, write, erase and refresh operations on the DRAM 140. Here, the storage controller 130 may be connected to, or it may include, a buffer memory, that may be used for temporary storage of data items before the data items are moved into the flash memory 125 or the DRAM 140.

In some embodiments the solid state drive 105 writes hot data items to the DRAM 140, and writes other data items (warm or cold data items) to physical blocks 110 in the flash memory. As a result, there may be no write amplification of hot data items. Write amplification may still occur with warm or cold data items, but because warm and cold data items are overwritten less frequently, the costs of this write amplification may be relatively small compared to the cost that would be incurred if the hot data items were affected by write amplification. The solid state drive 105 may report the total capacity of the flash memory 125 and of the DRAM 140 (less any flash memory reserved as overprovision blocks for garbage collection, and less any part of the flash memory 125 reserved for power-failure backup of the DRAM 140) when it reports its capacity, e.g., in response to a query from the host 100.

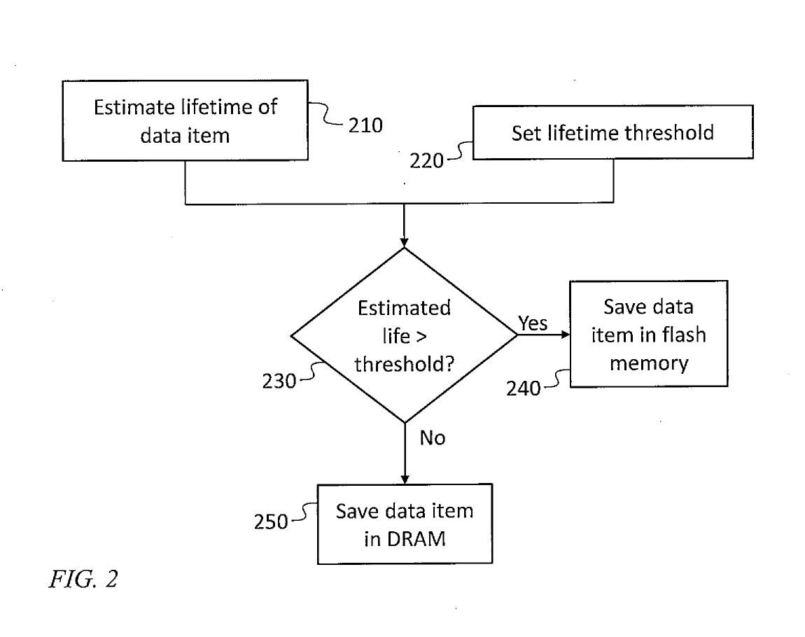

Referring to FIG. 2, in one embodiment, for any write operation executed in the solid state drive 105, a decision is made whether to write to the flash memory 125 or to the DRAM 140. This decision may be made in several acts, with each act being executed either on the host 100 or on the solid state drive 105. In an act 210, the lifetime of the data item to be written is estimated. This may be accomplished, for example, by tracking (and averaging) the lifetimes of similar data items, e.g., data items generated by the same virtual machine, or by the same application, or by the same kind of operation in an application or a virtual machine.

For example, journaling of database or file system data may result in data items that have a relatively short lifetime. Some applications may consistently or generally generate data items with shorter lifetimes than other applications, and similarly, some virtual machines may consistently or generally generate data items with shorter lifetimes than other virtual machines. In some such cases, the estimated lifetime of a data item may be known ahead of time, e.g., it may be understood when the software for an application is being written, or when an application is associated with a particular virtual machine, that the application will generate short-lifetime data items. In these cases, the host 100 may include in write commands for short-lifetime data items an attribute code that indicates the lifetime of the data items.

As used herein, an “attribute code” associated with a write command is any value (e.g., an integer, a floating point number, a character string, or a structure (e.g., an object) containing a combination of numerical and/or string values) that provides information about the estimated lifetime of the data item being written. The information may indicate, for example, which of several qualitative categories (e.g., “hot”, “warm”, or “cold”) the data item falls into, or stream identifier (e.g., if the attribute code is a stream identifier). Finer granularity than the three categories “hot”, “warm” or “cold” may be achieved by assigning each data item a “weight” (e.g., a floating point number between 0 and 1) instead of (or in addition to) classifying it into one of the three categories of lifetime (hot, warm, or cold). In some embodiments each write command includes an attribute code that may be an integer representing “hot”, “warm” or “cold”, an integer or floating point number representing, with finer (or coarser) granularity the anticipated lifetime of the data item, or any code (e.g., a number or a character string) that allows the solid state drive 105 to infer the anticipated or estimated lifetime of the data item to be written.

In other embodiments, the host 100 may instead include with the write command an attribute code that classifies the write command into a category, such as (as mentioned above), a stream associated with a stream identifier in a multi-streaming system. For example, the host 100 may include a process identifier for the application that generated the write command, or a process identifier for the virtual machine on which the application that generated the write command is running. The solid state drive 105 may then for example monitor the lifetimes of data items in write commands in each category and form a lifetime estimate for the category (e.g., for the application, if the category corresponds to a particular application). In this manner, the act 210 of estimating the lifetime may be performed on the host 100, or in the solid state drive 105, or some elements of the act 210 of estimating the lifetime may be performed on the host and other elements of the act 210 of estimating the lifetime may be performed on the solid state drive 105.

In an act 220 a lifetime threshold is set, e.g., by the storage controller 130. The act 220 of setting a lifetime threshold may be performed before, after, or concurrently with the act 210 of estimating the lifetime. The lifetime threshold may subsequently be used, in an act 230, to determine whether to write the data item to the flash memory 125 or to the DRAM 140. The lifetime threshold may be set sufficiently low that the likelihood of the DRAM 140 overflowing (resulting in the writing of hot data items to the flash memory 125) is low, and sufficiently high such that all or at least a substantial fraction of relatively hot data items are written to the DRAM 140, so that a significant reduction in write amplification, and significant improvements in performance and endurance, are achieved. The lifetime threshold may be set ahead of time, e.g., it may be hard-coded in the software or firmware of the storage controller 130, or it may be stored on the host and communicated to the solid state drive 105, e.g., at startup. In some embodiments the lifetime threshold is adjusted during operation (e.g., in real time) by the solid state drive 105, or by the host 100 (and communicated to the SSD), e.g., based on statistics of the lifetimes of previously written data items, or on the degree to which the DRAM 140 is full, or the like. As mentioned above, the estimated lifetime is compared, in an act 230, to the lifetime threshold. If the estimated lifetime is longer than the lifetime threshold, the data item is saved in the flash memory 125; otherwise it is saved in the DRAM 140. In some embodiments the host 100 or the solid state drive 105 monitors the lifetime of data items in write commands associated with each stream, sorts the streams according to a measure of estimated lifetime (e.g., the median or mean expected lifetime of the data items in the stream), and then selects all of the streams with associated lifetimes greater than a lifetime threshold to be saved in the flash memory 125.

Various methods may be used for communication between the host 100 and the solid state drive 105. In a solid state drive 105 with storage intelligence (i.e., a solid state drive 105 configured to receive, with each write command, a stream identifier) certain stream identifiers (corresponding to streams with data items having the shortest lifetimes) may be designated as ones for which write commands will be directed to the DRAM 140. For example the storage controller 130 may assign dedicated stream identifiers to the DRAM 140, so that when a write command including one of these dedicated stream identifiers is received, the solid state drive 105 will save the data item in the write command into the DRAM 140, if possible. In some embodiments, if the solid state drive 105 receives a write command with a hot data item that ordinarily would be written to the DRAM 140, and the DRAM 140 is full, the solid state drive 105 will instead write the data item to the flash memory 125. When DRAM 140 fills up or approaches being full (e.g., when the fraction of free space in the DRAM 140 falls below a set threshold), the solid state drive 105, or the host 100 (which may query the solid state drive 105 for the fraction of free space in the DRAM 140) may adjust (e.g., reduce) the lifetime threshold so that a smaller proportion of the received write commands are directed to the DRAM 140. Similarly, if the fraction of free space in the DRAM 140 exceeds an upper threshold, the solid state drive 105, or the host 100 may adjust (e.g., increase) the lifetime threshold so that a larger proportion of the received write commands are directed to the DRAM 140. The solid state drive 105 may expose an application program interface that enables the host 100 to query the solid state drive 105 for, e.g., a list of stream identifiers that are associated with hot data items and that are dedicated to the DRAM 140. It may also allow the host 100 to query the solid state drive 105 for other lists of stream identifiers, e.g., ones that are associated with warm data items or cold data items.

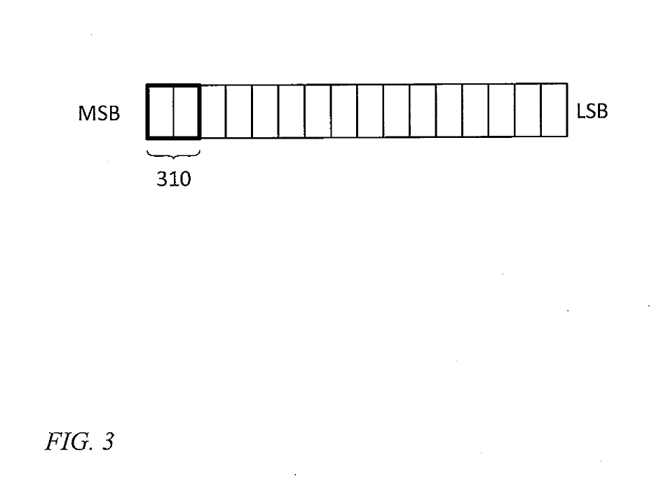

Referring to FIG. 3 in some embodiments, a stream identifier may be a 16-bit unsigned integer, and the two most significant bits (MSBs) 310 may be reserved to communicate lifetime codes, with, e.g., the value 00b (the binary representation of the decimal value 0) indicating cold data items (or other data items), the value 01b (the binary representation of the decimal value 1) indicating warm data items, and the value 10b (the binary representation of the decimal value 2) indicating hot data items. The remaining bits (e.g., the remaining 14 bits) of the stream identifier may then be assigned by the host according to other criteria (e.g., assigned in numerical order as new streams are created). In some embodiments more (or fewer) than 2 bits may be used for the lifetime code.

In a generic solid state drive 105, e.g., one that does not have storage intelligence (a device that is not configured to receive stream identifiers and process write commands accordingly), various other methods may be used. For example, the two most significant bits (MSBs) of the starting logical block address of a write command may be reserved to communicate lifetime codes. In other embodiments the group ID field of Serial Advanced Technology Attachment (SATA) IO command or of a Small Computer System Interface (SCSI) IO command, or the Data Set Management (DSM) field of a Non Volatile Memory Express (NVMe) IO command, may be used to communicate lifetime codes. In some embodiments, in a system running Linux, the “bi_flags” or “bio” structure may include a lifetime code, e.g., it may be used to specify whether a data item is hot or cold.

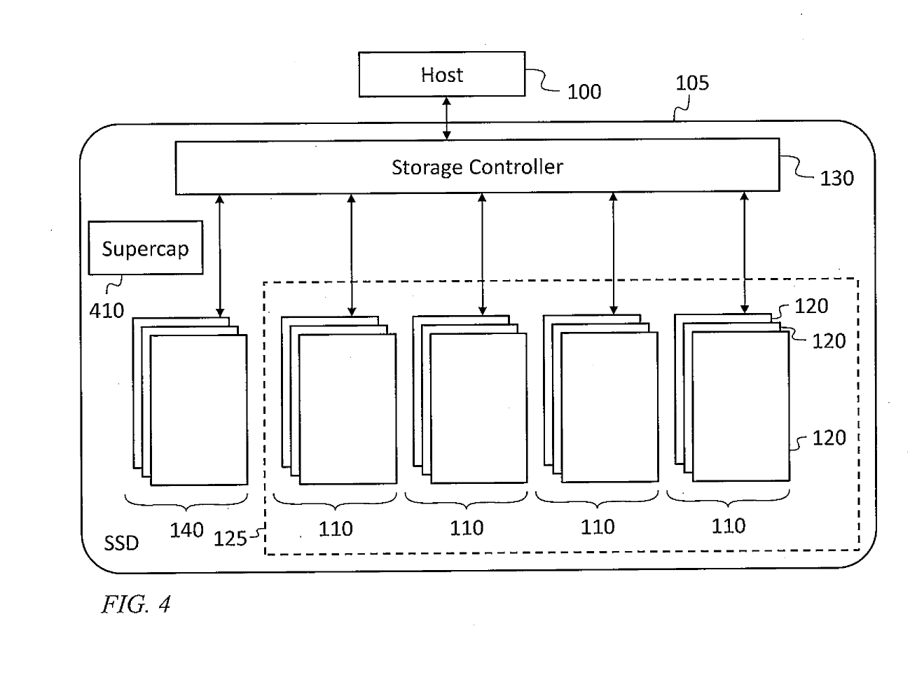

Referring to FIG. 4, in one embodiment, the solid state drive 105 includes an energy storage device 410 such as a supercapacitor (or “supercap”) or battery. When power to the solid state drive 105 is interrupted, the energy storage device 410 provides power to the solid state drive 105 for a sufficiently long time to allow the storage controller 130 to move all of the data stored in the DRAM 140 to the flash memory 125, so that it is not lost.

In some embodiments a software daemon inside the solid state drive 105 monitors IO activity, moves hot data stored in physical blocks in the flash memory 125 into the DRAM 140, and remaps (e.g., adjusts the mapping from logical block addresses or logical page number to physical blocks and physical pages to reflect the new location of the data moved to the DRAM 140). The physical blocks in the flash memory 125 may then be added back into a free block table.

The storage controller 130 may be connected to the storage interface, to a buffer memory, to the flash memory 125, and to the DRAM 140. The buffer memory may be used for temporary storage of data items before the data items are moved into the flash memory 125 or the DRAM 140. In some embodiments, when the solid state drive 105 receives a write command including a data item, the data item is temporarily stored in the buffer, and then moved to either the flash memory 125 or the DRAM 140 (e.g. the data item is stored in the flash memory 125, or the DRAM 140, but not in both). In the context of embodiments of the present invention, the operation and/or structure of the buffer memory is different from that of the non-flash memory, such as the DRAM 140, as should be apparent to one of skill in the art. For example, when a data item is to be stored in the flash memory, it may be temporarily stored in the buffer before being copied to the flash memory 125, whereas (except in the case of a power outage) it may not be the case that a data item is first stored in the non-flash memory (such as the DRAM 140), and then copied to the flash memory 125.

Thus, embodiments according to the present invention provide a system and method for improving the performance and endurance of a solid state drive.

In some embodiments, elements of the host 100 or the solid state drive 105 (e.g., the storage controller 130) may be processing units. The term “processing unit” is used herein to include any combination of hardware, firmware, and software, employed to process data or digital signals. Processing unit hardware may include, for example, application specific integrated circuits (ASICs), general purpose or special purpose central processing units (CPUs), digital signal processors (DSPs), graphics processing units (GPUs), and programmable logic devices such as field programmable gate arrays (FPGAs). In a processing unit, as used herein, each function is performed either by hardware configured, i.e., hard-wired, to perform that function, or by more general purpose hardware, such as a CPU, configured to execute instructions stored in a non-transitory storage medium. A processing unit may be fabricated on a single printed wiring board (PWB) or distributed over several interconnected PWBs. A processing unit may contain other processing units; for example a processing unit may include two processing units, an FPGA and a CPU, interconnected on a PWB.

The solid state drive and/or any other relevant devices or components according to embodiments of the present invention described herein may be implemented utilizing any suitable hardware, firmware (e.g. an application-specific integrated circuit), software, or a combination of software, firmware, and hardware. For example, the various components of the solid state drive may be formed on one integrated circuit (IC) chip or on separate IC chips. Further, the various components of the solid state drive may be implemented on a flexible printed circuit film, a tape carrier package (TCP), a printed circuit board (PCB), or formed on one substrate. Further, the various components of the solid state drive may be may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the exemplary embodiments of the present invention.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section, without departing from the spirit, and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that such spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the terms “substantially,” “about,” and similar terms are used as terms of approximation and not as terms of degree, and are intended to account for the inherent deviations in measured or calculated values that would be recognized by those of ordinary skill in the art. As used herein, the term “major component” means a component constituting at least half, by weight, of a composition, and the term “major portion”, when applied to a plurality of items, means at least half of the items.

As used herein, the singular forms “a” and “an” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Further, the use of “may” when describing embodiments of the inventive concept refers to “one or more embodiments of the present invention”. Also, the term “exemplary” is intended to refer to an example or illustration. As used herein, the terms “use,” “using,” and “used” may be considered synonymous with the terms “utilize,” “utilizing,” and “utilized,” respectively.

It will be understood that when an element or layer is referred to as being “on”, “connected to”, “coupled to”, or “adjacent to” another element or layer, it may be directly on, connected to, coupled to, or adjacent to the other element or layer, or one or more intervening elements or layers may be present. In contrast, when an element or layer is referred to as being “directly on”, “directly connected to”, “directly coupled to”, or “immediately adjacent to” another element or layer, there are no intervening elements or layers present.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein.

Although exemplary embodiments of an improvement of SSD performance and endurance have been specifically described and illustrated herein, many modifications and variations will be apparent to those skilled in the art. Accordingly, it is to be understood that an improvement of SSD performance and endurance constructed according to principles of this invention may be embodied other than as specifically described herein. The invention is also defined in the following claims, and equivalents thereof.

What is claimed is:

1. A solid state drive, comprising:
a flash memory;
a non-flash memory;
a storage controller; and
a storage interface,
the storage controller being connected to the storage interface and configured to receive, through the storage interface, a plurality of write commands, each write command comprising:
a data item to be written; and
an attribute code,
the storage controller being configured to store the data item
in the flash memory or in the non-flash memory,
based on the attribute code.

2. The solid state drive of claim 1, wherein the attribute code is a stream identifier classifying the write command into one of a plurality of categories based on estimated data item lifetime.

3. The solid state drive of claim 1, wherein the storing of the data item
in the flash memory or in the non-flash memory,
based on the attribute code
comprises:
inferring an estimated lifetime of the data item from the attribute code;
storing the data item in the flash memory when the estimated lifetime is greater than a lifetime threshold; and
storing the data item in the non-flash memory when the estimated lifetime is not greater than a lifetime threshold.

4. The solid state drive of claim 1,
wherein the attribute code is equal to one selected from the group consisting of:
a first value when the data item has a lifetime that falls into a first range of lifetimes,
a second value when the data item has a lifetime that falls into a second range of lifetimes, and
a third value when the data item has a lifetime that falls into a third range of lifetimes,
the first range, the second range; and the third range being non-overlapping, a lifetime in the first range being shorter than a lifetime in the second range and shorter than a lifetime in the third range, and
wherein the storing of the data item
in the flash memory or in the non-flash memory,
based on the attribute code
comprises:
storing the data item in the non-flash memory when the attribute code takes the first value; and
storing the data item in the flash memory when the attribute code takes the second value or the third value.

5. The solid state drive of claim 1, further comprising an energy storage device capable of storing an amount of energy sufficient to power the solid state drive during a time interval longer than a time interval sufficient to copy all data from the non-flash memory into the flash memory.

6. The solid state drive of claim 5, wherein the energy storage device is a supercapacitor.

7. A system comprising:
a host; and
a solid state drive comprising:
a flash memory;
a non-flash memory;
a storage controller; and
a storage interface,
the host being configured to send to the storage controller, through the storage interface, a plurality of write commands, each write command comprising:
a data item to be written; and
an attribute code,
the storage controller being configured to store the data item
in the flash memory or in the non-flash memory,
based on the attribute code.

8. The system of claim 10, wherein:
the system is configured to define a plurality of stream identifiers, each associated with a respective host activity;
the attribute code of each write command is a stream identifier of the plurality of stream identifiers; and
the system is further configured:
to select a first subset of the stream identifiers;
to store the data item in the flash memory when the stream identifier is in the first subset; and
to store the data item in the non-flash memory when the stream identifier is not in the first subset.

9. The system of claim 8, wherein the selecting, of the first subset of the plurality of stream identifiers comprises:
monitoring data lifetimes of data items in write commands associated with each of the stream identifiers;
associating an average lifetime with each stream identifier; and
selecting, as the subset, a set of stream identifiers associated with a lifetime greater than a first threshold.

10. The system of claim 7, wherein the storing of the data item
in the flash memory or in the non-flash memory,
based on the attribute code
comprises:
inferring an estimated lifetime of the data item from the attribute code;
storing the data item in the flash memory when the estimated lifetime is greater than a lifetime threshold; and
storing the data item in the non-flash memory when the estimated lifetime is not greater than a lifetime threshold.

11. The system of claim 10, wherein:
the attribute code takes one of a first value, a second value, or a third value when the data item has a lifetime that falls into a first range of lifetimes, a second range of lifetimes, and a third range of lifetimes, respectively,
the first range, the second range, and the third range being non-overlapping, a lifetime in the first range being shorter than a lifetime in the second range and shorter than a lifetime in the third range, and
wherein the storing of the data item
in the flash memory or in the non-flash memory,
based on the attribute code
comprises:
storing the data item in the non-flash memory when the attribute code takes the first value; and
storing the data item in the flash memory when the attribute code takes the second value or the third value.

12. The system of claim 7, wherein the storage interface conforms to a standard selected from the group consisting of: Serial Advanced Technology Attachment (SATA), Fibre Channel, Serial Attached SCSI (SAS), Non Volatile Memory Express (NVMe), Ethernet, and Universal Serial Bus (USB).

13. The system of claim 7, wherein the flash memory comprises a plurality of physical blocks, each physical block comprising a plurality of physical pages, and wherein a size of the non-flash memory is an integer multiple of a size of a physical page.

14. The system of claim 13, wherein the flash memory comprises a plurality of physical blocks, each physical block comprising a plurality of physical pages, and wherein a size of the non-flash memory is an integer multiple of a size of a physical block.

15. The system of claim 7 further comprising an energy storage device capable of storing an amount of energy sufficient to power the solid state drive during a time interval longer than a time interval sufficient to copy all data from the non-flash memory into the flash memory.

16. The system of claim 15 wherein the energy storage device is a supercapacitor.

17. A method for storing data, the method comprising:
sending, by a host, through a storage interface, to a solid state drive comprising a flash memory and a non-flash memory, a plurality of write commands, each of the write commands comprising a data item to be stored and an attribute code, and
storing the data item, based on the attribute code, either
in the flash memory, or
in the non-flash memory.

18. The method of claim 17, wherein the attribute code is a stream identifier classifying the write command into one of a plurality of categories based on estimated data item lifetime.

19. The method of claim 17, wherein the storing of the data item
in the flash memory or in the non-flash memory,
based on the attribute code
comprises:
inferring an estimated lifetime of the data item from the attribute code;
storing the data item in the flash memory when the estimated lifetime is greater than a lifetime threshold; and
storing the data item in the non-flash memory when the estimated lifetime is not greater than a lifetime threshold.

20. The method of claim 17,
wherein the attribute code is equal to one selected from the group consisting of:
a first value when the data item has a lifetime that falls into a first range of lifetimes,
a second value when the data item has a lifetime that falls into a second range of lifetimes, and
a third value when the data item has a lifetime that falls into a third range of lifetimes,
the first range, the second range, and the third range being non-overlapping, a lifetime in the first range being shorter than a lifetime in the second range and shorter than a lifetime in the third range, and
wherein the storing of the data item
in the flash memory or in the non-flash memory,
based on the attribute code
comprises:
storing the data item in the non-flash memory when the attribute code takes the first value; and
storing the data item in the flash memory when the attribute code takes the second value or the third value.
